(19) United States
(12) Patent Application Publication
(10) Pub. No.: US 2021/0199352 A1
(43) Pub. Date: Jul. 1, 2021

(54) ELECTROCALORIC HEAT TRANSFER ARTICLES AND SYSTEMS

(71) Applicant: Carrier Corporation, Palm Beach Gardens, FL (US)

(72) Inventors: Wei Xie, Maiden, MA (US); Joseph V. Mantese, Ellington, CT (US); Scott Alan Eastman, Glastonbury, CT (US); Subramanyaravi Annapragada, South Windsor, CT (US); William A. Rioux, Willington, CT (US); Parmesh Verma, South Windsor, CT (US)

(21) Appl. No.: 17/058,487

(22) PCT Filed: Aug. 21, 2019
(86) PCT No.: PCT/US2019/047449

§ 371 Date: Nov. 24, 2020

Related U.S. Application Data
(60) Provisional application No. 62/722,770, filed on Aug. 24, 2018.

(51) Int. Cl. F25B 21/00

(52) U.S. Cl. CPC F25B 21/00; F25B 2321/001

(57) ABSTRACT

A heat transfer system is disclosed that includes a plurality of supported electrocaloric film segments (46) arranged in a stack and connected to a frame (10). A working fluid flow path (44) extends through the stack, disposed between adjacent electrocaloric film segments. The working fluid flow path is in operative thermal communication with a heat sink and a heat source at opposite ends of the working fluid flow path. A plurality of electrodes are arranged to generate an electric field in the electrocaloric film segments, and are connected to a power source configured to selectively apply voltage to activate the electrodes in coordination with fluid flow along the working fluid flow path to transfer heat from the heat source to the heat sink. The heat transfer system further includes a film stress management mechanism.

### BACKGROUND

A wide variety of technologies exist for cooling applications, including but not limited to evaporative cooling, convective cooling, or solid state cooling such as electrothermic cooling. One of the most prevalent technologies in use for residential and commercial refrigeration and air conditioning is the vapor compression refrigerant heat transfer loop. These loops typically circulate a refrigerant having appropriate thermodynamic properties through a loop that includes a compressor, a heat rejection heat exchanger (i.e., heat exchanger condenser), an expansion device and a heat absorption heat exchanger (i.e., heat exchanger evaporator). Vapor compression refrigerant loops effectively provide cooling and refrigeration in a variety of settings, and in some situations can be run in reverse as a heat pump. However, many of the refrigerants can present environmental hazards such as ozone depleting potential (ODP) or global warming potential (GWP), or can be toxic or flammable. Additionally, vapor compression refrigerant loops can be impractical or disadvantageous in environments lacking a ready source of power sufficient to drive the mechanical compressor in the refrigerant loop. For example, in an electric vehicle, the power demand of an air conditioning compressor can result in a significantly shortened vehicle battery life or driving range. Similarly, the weight and power requirements of the compressor can be problematic in various portable cooling applications.

Accordingly, there has been interest in developing cooling technologies as alternatives to vapor compression refrigerant loops. Various technologies have been proposed such as field-active heat or electric current-responsive heat transfer systems relying on materials such as electrocaloric materials, magnetocaloric materials, or thermoelectric materials. However, many proposals have been configured as bench-scale demonstrations with limited capabilities.

### BRIEF DESCRIPTION

A heat transfer system is disclosed that includes a plurality of supported electrocaloric film segments arranged in a stack and connected to a frame. A working fluid flow path extends through the stack, disposed between adjacent electrocaloric film segments. The working fluid flow path is in operative thermal communication with a heat sink and a heat source at opposite ends of the working fluid flow path. A plurality of electrodes are arranged to generate an electric field in the electrocaloric film segments, and are connected to a power source configured to selectively apply voltage to activate the electrodes in coordination with fluid flow along the working fluid flow path to transfer heat from the heat source to the heat sink. The heat transfer system further includes a film stress management mechanism selected from:

a change in electrocaloric film thickness from a first film thickness at a first location on an electrocaloric film segment to a second film thickness at a second location on the electrocaloric film segment, wherein the change in electrocaloric film thickness includes a continuous change in thickness from the first thickness to the second thickness, or wherein the first location is at an edge of an active area of the electrocaloric film and the second location is remote from the edge of the active area of the electrocaloric film; or

an electrode comprising an electrically-conductive material on a surface portion of an electrocaloric film segment surface that includes a non-linear edge between the electrically-conductive surface portion and the electrocaloric film segment surface outside of the electrically conductive surface portion; or

an electrocaloric film segment that includes an active area and a non-active area, and the non-active area is interposed between the frame and the active area to provide a separation between the active area and the frame of at least 10 times the thickness of the electrocaloric film; or

an elastic interface between an electrocaloric film segment and the frame; or

a movable or deformable frame component; or

a reinforcing material disposed in or on an electrocaloric film segment or an electroctrode.

In some embodiments, the stress management mechanism includes a change in electrocaloric film thickness from a first film thickness at a first location on an electrocaloric film segment to a second film thickness at a second location on the electrocaloric film segment, wherein the change in electrocaloric film thickness includes a continuous change in thickness from the first thickness to the second thickness, or wherein the first location is at an edge of an active area of the electrocaloric film and the second location is remote from the edge of the active area of the electrocaloric film.

In some embodiments, the change in electrocaloric film thickness can include a continuous change in thickness from the first thickness to the second thickness.

In any one or combination of the foregoing embodiments, the first location can be at an edge of an active area of the electrocaloric film and the second location is remote from the edge of the active area of the electrocaloric film.

In any one or combination of the foregoing embodiments, the electrocaloric film can have the second thickness at locations on both sides of the edge of the active area.

In any one or combination of the foregoing embodiments, the change in electrocaloric film thickness can include a surface departure angle of less than 45° from a surface portion of constant thickness.

In any one or combination of the foregoing embodiments, the change in electrocaloric film thickness can include a surface departure angle of less than 30° from a surface of a thicker of first and second portions of constant thickness.

In any one or combination of the foregoing embodiments, the change in electrocaloric film thickness can include a surface departure angle of less than 15° from a surface of a thinner of first and second portions of constant thickness.

In any one or combination of the foregoing embodiments, the change in electrocaloric film thickness can include a surface departure angle of less than 5° from a surface of a thinner of first and second portions of constant thickness.

In any one or combination of the foregoing embodiments, electrocaloric film surface can include a fillet configuration on an angle between adjacent surfaces.

In any one or combination of the foregoing embodiments, the change in electrocaloric film thickness can include a film surface profile that includes a convex portion and a concave portion.

In any one or combination of the foregoing embodiments, the stress management mechanism can include an electrode comprising an electrically-conductive material on a surface portion of an electrocaloric film segment surface that includes a non-linear edge between the electrically-conductive surface portion and the electrocaloric film segment surface outside of the electrically conductive surface portion.

In any one or combination of the foregoing embodiments, the electrode comprises a patterned disposition of conductive material can comprise a plurality of areas on the film surface comprising the conductive material separated by spacer areas on the film that do not comprise the conductive material.

In any one or combination of the foregoing embodiments, the electrode can be configured as a plurality of electrically connected linear extensions of conductive material along the film surface separated by spacer areas.

In any one or combination of the foregoing embodiments, the stress management mechanism can include an electrocaloric film segment that includes an active area and a non-active area, and the non-active area is interposed between the frame and the active area to provide a separation between the active area and the frame of at least 10 times the thickness of the electrocaloric film.

In any one or combination of the foregoing embodiments, the stress management mechanism can include an electrocaloric film segment that includes an active area and a non-active area, and the non-active area is interposed between the frame and the active area to provide a separation between the active area and the frame of at least 100 times the thickness of the electrocaloric film.

In any one or combination of the foregoing embodiments, the stress management mechanism can include an electrocaloric film segment that includes an active area and a non-active area, and the non-active area is interposed between the frame and the active area to provide a separation between the active area and the frame of at least 200 times the thickness of the electrocaloric film.

In any one or combination of the foregoing embodiments, the stress management mechanism can include a movable or deformable frame component.

In any one or combination of the foregoing embodiments, wherein the stress management mechanism can include an elastic interface between an electrocaloric film segment and the frame.

In any one or combination of the foregoing embodiments, the stress management mechanism can include a reinforcing material disposed in or on an electrocaloric film segment or an electroctrode.

In any one or combination of the foregoing embodiments, the reinforcing material can be disposed in an electrocaloric film segment.

In any one or combination of the foregoing embodiments, the reinforcing material can be disposed on an electrocaloric film.

In any one or combination of the foregoing embodiments, the reinforcing material can be disposed on an electrode.

In any one or combination of the foregoing embodiments, the reinforcing material can include a mesh.

In any one or combination of the foregoing embodiments, the reinforcing material can include a solid sheet.

### BRIEF DESCRIPTION OF THE DRAWINGS

The following descriptions should not be considered limiting in any way. With reference to the accompanying drawings, like elements are numbered alike:

FIG. 1 is a schematic depiction of an example embodiment of an electrocaloric heat transfer system;

FIGS. 2A and 2B each schematically shows an example embodiment of a peripheral frame component of a heat transfer system;

FIG. 3 schematically shows an example embodiment of a plurality of framed electrocaloric film segments in a stacked configuration;

FIG. 4 schematically shows an electrocaloric article with plurality of connected aligned segments of electrocaloric film in a stack-like configuration;

FIG. 5 schematically shows an example embodiment of a film stress management mechanism in the form of a thickened electrocaloric film at an edge of an active area of the electrocaloric film;

FIGS. 6A and 6B schematically show a change in thickness of an electrocaloric film provided by a fillet configuration;

FIG. 7 schematically shows a change in thickness of an electrocaloric film including a surface profile characterized by a sigmoid function;

FIGS. 8A, 8B, 8C, and 8D schematically show example embodiments of an electrode configuration with a non-linear edge;

FIG. 9 schematically shows an electrocaloric film segment with a non-active portion of electrocaloric film between an active portion of the electrocaloric film and a frame;

FIG. 10 schematically shows an elastic interface between an electrocaloric film segment and a frame; and

FIGS. 11A, 11B, and 11C schematically show example embodiments of an electrocaloric film segment with a reinforcing material.

### DETAILED DESCRIPTION

A detailed description of one or more embodiments of the disclosed apparatus and method are presented herein by way of exemplification and not limitation with reference to the Figures.

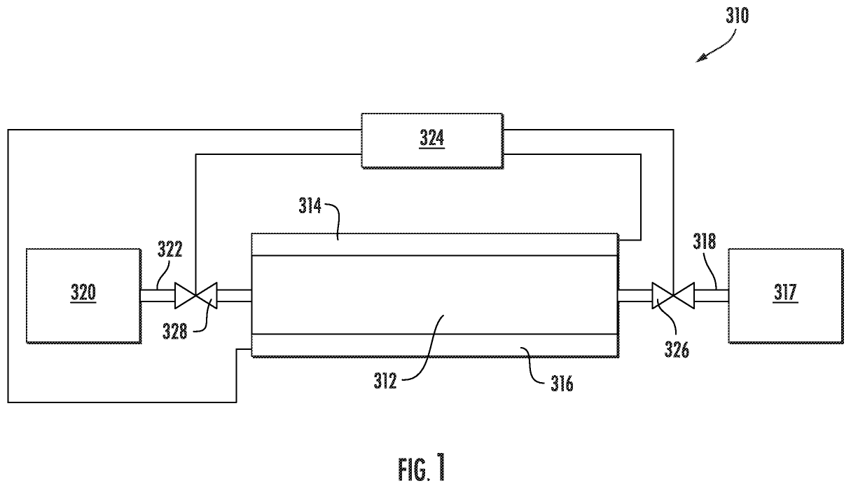

An example embodiment of a heat transfer system and its operation are described with respect to FIG. 1. As shown in FIG. 1, a heat transfer system 310 comprises an electrocaloric material 312 with first and second electrical buses 314 and 316 in electrical communication with electrodes on the electrocaloric material. The electrocaloric material 312 is in thermal communication with a heat sink 317 through a first thermal flow path 318, and in thermal communication with a heat source 320 through a second thermal flow path 322. The thermal flow paths are described below with respect thermal transfer through flow of working fluid through control devices 326 and 328 (e.g., flow dampers) between the stack and the heat sink and heat source. A controller 324 is configured to control electrical current to through a power source (not shown) to selectively activate the buses 314, 316. In some embodiments, the electrocaloric material can be activated energizing one bus bar/electrode while maintaining the other bus bar/electrode at a ground polarity. The controller 324 is also configured to open and close control devices 326 and 328 to selectively direct the working fluid along the first and second flow paths 318 and 322.

In operation, the system 310 can be operated by the controller 324 applying an electric field as a voltage differential across the electrocaloric material 312 in the stack to cause a decrease in entropy and a release of heat energy by the electrocaloric material 312. The controller 324 opens the control device 326 to transfer at least a portion of the released heat energy along flow path 318 to heat sink 317. This transfer of heat can occur after the temperature of the electrocaloric material 312 has risen to a threshold temperature. In some embodiments, heat transfer to the heat sink 317 is begun as soon as the temperature of the electrocaloric material 312 increases to be about equal to the temperature of the heat sink 317. After application of the electric field for a time to induce a desired release and transfer of heat energy from the electrocaloric material 312 to the heat sink 317, the electric field can be removed. Removal of the electric field causes an increase in entropy and a decrease in heat energy of the electrocaloric material 312. This decrease in heat energy manifests as a reduction in temperature of the electrocaloric material 312 to a temperature below that of the heat source 320. The controller 324 closes control device 326 to terminate flow along flow path 318, and opens control device 328 to transfer heat energy from the heat source 320 to the colder electrocaloric material 312 in order to regenerate the electrocaloric material 312 for another cycle.

In some embodiments, for example where a heat transfer system is utilized to maintain a temperature in a conditioned space or thermal target, the electric field can be applied to the electrocaloric material 312 to increase temperature until the temperature reaches a first threshold. After the first temperature threshold, the controller 324 opens control device 326 to transfer heat from the stack to the heat sink 317 until a second temperature threshold is reached. The electric field can continue to be applied during all or a portion of the time period between the first and second temperature thresholds, and is then removed to reduce the temperature until a third temperature threshold is reached. The controller 324 then closes control device 326 to terminate heat flow transfer along heat flow path 318, and opens control device 328 to transfer heat from the heat source 320 to the stack. The above steps can be optionally repeated until a target temperature of the conditioned space or thermal target (which can be either the heat source or the heat sink) is reached.

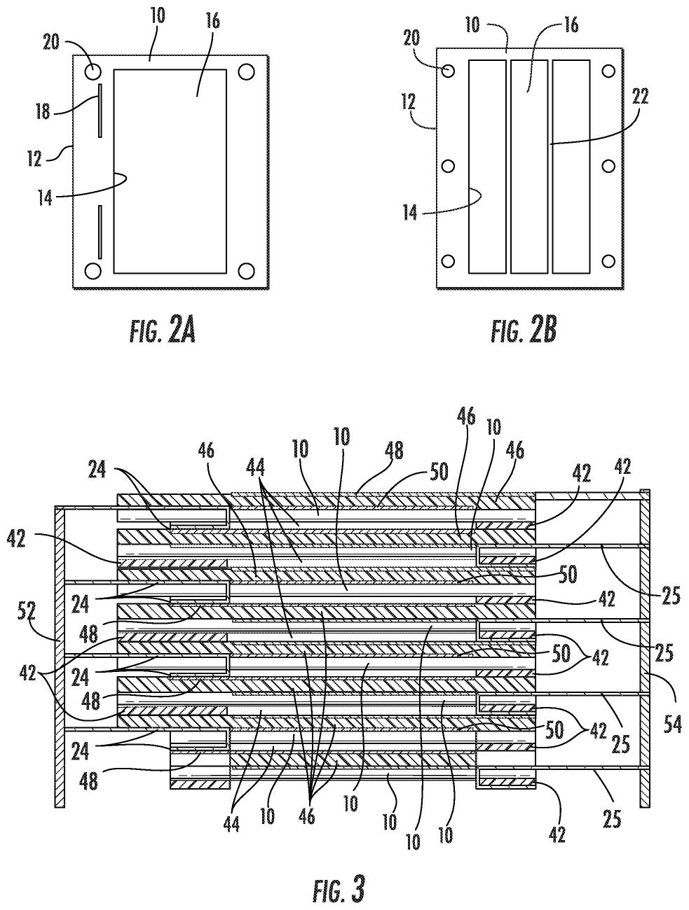

According to this disclosure, the electrocaloric material 312 referenced above comprises an electrocaloric film connected to a frame. The frame can include various configurations, including but not limited to full peripheral frames (e.g., ‘picture’ frames) and components thereof, partial peripheral frames and components thereof, or internal frames and components thereof. In some embodiments, the frame can be part of a repeating modular structure that can be assembled along with a set of electrocaloric films in a stack-like fashion. In some embodiments, the frame can be a unitary structure equipped with one or more attachment points to receive one or more of electrocaloric films. Example embodiments of modular peripheral frames 10 are shown in FIGS. 2A and 2B. As shown in FIGS. 2A and 2B, the peripheral frames 10 have an outer perimeter 12 and an inner perimeter 14, which surrounds a central opening 16. In some embodiments, the inner perimeter 14 can be rounded, tapered, or otherwise modified to address the effects of mechanical rubbing, folding or cutting of the film from the inner perimeter edge. In some embodiments, the peripheral frame 10 can have slots 18 therein, which can go through the frame. The slots 18 can provide a pathway for connections such as power connections to electrodes on the electrocaloric films or to internal sensors such as temperature or flow sensors. In some embodiments, the peripheral frame 10 can include one or alignment or retention features. For example, through-passages such as holes 20 can be utilized to align the frames 10 and other modular components, and can also accommodate retention features such as stack assembly bolts. In some embodiments, a rectangular peripheral frame 10 can include four or more alignment and/or retention features such as holes 20. Other types of alignment or retention features can be used by themselves or in combination, including but not limited to tabs, recesses, notches, interlocking features, external stack clamps or bands. In some embodiments, the peripheral frame can include one or more supports such as ribs 22 extending partly or completely across the opening 16, which can help provide support for electrocaloric films to be disposed in the opening 16. The ribs 22 can extend in various directions, including parallel to fluid flow, perpendicular to fluid flow, other orientations to fluid flow, or non-linear. In some embodiments, the support can be in the form of a sheet such as a mesh or other porous sheet extending parallel to the plane of the electrocaloric film, and can occupy a footprint in that plane that is smaller than, the same as, or larger than the footprint of the electrocaloric film.

In some embodiments, the illustrated frames are rectangular in shape, which can provide convenient edge surfaces along the module(s) for connecting functional components such as fluid flow inlet/outlet or conduits, electrical connections, etc. However, any other shape can be used including but not limited to circular, ovular, rectangular, etc. In some embodiments, the peripheral frame can extend completely around the perimeter of the film, but in some embodiments, the peripheral frame may engage with only a portion of the film perimeter. In some embodiments, multiple perimeter frame components can be used with each component covering some portion of the film perimeter. In some embodiments, the peripheral frame can be electrically non-conductive. In some embodiments, the peripheral frame can be electrically conductive. The peripheral frame can be made of various materials, including but not limited to plastics (e.g., moldable thermoplastics such as polypropylene and thermosets such as epoxy), ceramics, aerogels, cardboard, fiber composites, or metals.

As mentioned above, the frame has an electrocaloric film connected thereto. Examples of electrocaloric materials for the electrocaloric film can include but are not limited to inorganic (e.g., ceramics) or organic materials such as electrocaloric polymers, and polymer/ceramic composites. Composite materials such as organic polymers with inorganic fillers and/or fillers of a different organic polymer. Examples of inorganic electrocaloric materials include but are not limited to PbTiO₃ (“PT”), Pb(Mg_{1/3}Nb_{2/3})O₃ (“PMN”), PMN-PT, LiTaO₃, barium strontium titanate (BST) or PZT (lead, zirconium, titanium, oxygen). Examples of electrocaloric polymers include, but are not limited to ferroelectric polymers, liquid crystal polymers, and liquid crystal elastomers. Ferroelectric polymers are crystalline polymers, or polymers with a high degree of crystallinity, where the crystalline alignment of polymer chains into lamellae and/or spherulite structures can be modified by application of an electric field. Such characteristics can be provided by polar structures integrated into the polymer backbone or appended to the polymer backbone with a fixed orientation to the backbone. Examples of ferroelectric polymers include polyvinylidene fluoride (PVDF), polytriethylene fluoride, odd-numbered nylon, copolymers containing repeat units derived from vinylidene fluoride, and copolymers containing repeat units derived from triethylene fluoride. Polyvinylidene fluoride and copolymers containing repeat units derived from vinylidene fluoride have been widely studied for their ferroelectric and electrocaloric properties. Examples of vinylidene fluoride-containing copolymers include copolymers with methyl methacrylate, and copolymers with one or more halogenated co-monomers including but not limited to trifluoroethylene, tetrafluoroethylene, chlorotrifluoroethylene, trichloroethylene, vinylidene chloride, vinyl chloride, and other halogenated unsaturated monomers. In some embodiments, the electrocaloric film can include a polymer composition according to WO 2018/004518 A1 or WO 2018/004520 A1, the disclosures of which are incorporated herein by reference in their entirety.

Liquid crystal polymers, or polymer liquid crystals comprise polymer molecules that include mesogenic groups. Mesogenic molecular structures are well-known, and are often described as rod-like or disk-like molecular structures having electron density orientations that produce a dipole moment in response to an external field such as an external electric field. Liquid crystal polymers typically comprise numerous mesogenic groups connected by non-mesogenic molecular structures. The non-mesogenic connecting structures and their connection, placement and spacing in the polymer molecule along with mesogenic structures are important in providing the fluid deformable response to the external field. Typically, the connecting structures provide stiffness low enough so that molecular realignment is induced by application of the external field, and high enough to provide the characteristics of a polymer when the external field is not applied. In some exemplary embodiments, a liquid crystal polymer can have rod-like mesogenic structures in the polymer backbone separated by non-mesogenic spacer groups having flexibility to allow for re-ordering of the mesogenic groups in response to an external field. Such polymers are also known as main-chain liquid crystal polymers. In some exemplary embodiments, a liquid crystal polymer can have rod-like mesogenic structures attached as side groups attached to the polymer backbone. Such polymers are also known as side-chain liquid crystal polymers. Electrodes on the electrocaloric film can take different forms with various electrically conductive components. The electrodes can be any type of conductive material, including but not limited to metallized layers of a conductive metal such as aluminum or copper, or other conductive materials such as carbon (e.g., carbon nanotubes, graphene, or other conductive carbon). Noble metals can also be used, but are not required. Other conductive materials such as a doped semiconductor, ceramic, or polymer, or conductive polymers can also be used. In some embodiments, the electrodes can be in the form of metalized layers or patterns on each side of the film such as disclosed in published PCT application WO 2017/111921 A1 or U.S. patent application 62/521,080, the disclosures of each of which is incorporated herein by reference in its entirety.

In some embodiments, electrocaloric film thickness can be in a range having a lower limit of 0.1 μm, more specifically 0.5 μm, and even more specifically 1 μm. In some embodiments, the film thickness range can have an upper limit of 1000 μm, more specifically 100 μm, and even more specifically 10 μm. It is understood that these upper and lower range limits can be independently combined to disclose a number of different possible ranges. Within the above general ranges, it has been discovered that thinner films can promote efficiency by reducing parasitic thermal losses, compared to thicker films.

In some embodiments, a heat transfer device can include a plurality of electrocaloric films in a stack configuration arranged to provide flow paths for a working fluid between adjacent electrocaloric films. In some embodiments, the stack can include spacers between adjacent modules to provide space for such flow paths. In some embodiments, the spacers can be disposed between adjacent peripheral frames 10. Multiple spacers can be stacked together, optionally with different profiles to create 3D structures. Alternatively, or in addition to discrete spacers, portions of the peripheral frame can formed with a thickness (i.e., in a direction parallel with stack height) along the periphery of the peripheral frame 10 to provide space between adjacent electrocaloric elements, thereby reducing or eliminating the need for a discrete spacer. In some embodiments, spacers can be disposed in the area of opening 16 between adjacent electrocaloric film segments, and can be integrated with the peripheral frame 10 such as shown for ribs 22 or can be discrete structures. In some embodiments, It should be noted that any structures disposed in the fluid flow space (e.g., ribs 22 or discrete spacers) should be configured to allow for fluid flow. For example, such structures can be configured as strips disposed in a in a straight-line or non-straight-line longitudinal direction generally parallel to the direction of fluid flow, and/or can be formed from a fluid-permeable material such as a mesh or screen configuration. Additionally supports can be made from tensioned filament, strand, yarn, thread or other 1 dimensional materials that can be wound around assembly bolts such as bolts through the holes. In some embodiments, spacer structures disposed in the fluid flow space between adjacent electrocaloric films can be made of a flexible material or structure to accommodate displacement of the electrocaloric films during energization/de-energization cycling. In some embodiments, spacer structures disposed in the fluid flow space can be in the form of a mesh or other porous sheet parallel to the electrocaloric film, and can have a footprint in that plane that is smaller than, the same as, or larger than the footprint of the electrocaloric film. In some embodiments, spacer structures between electrocaloric element electrodes at the same voltage can be electrically conductive spacer structures, which can be fabricated using printed circuit board fabrication techniques and can serve both as spacer and as electrically conductive elements. In some embodiments, the spacer can be disposed as one or more mesh or screen spacers between adjacent electrocaloric films, which can in some embodiments be configured as a mat disposed in a plane parallel to the electrocaloric film.

A stack of repeating modular framed electrocaloric films 46 is schematically shown in FIG. 3. The order of assembly can be varied and adapted to achieve target specifications, and the order shown in FIG. 3 is a typical example including peripheral frames 10, spacers 42, electrocaloric elements having electrocaloric films 46 with first electrodes 48 and second electrodes 50, and first and second electrically conductive elements 24, 25 electrically connected to the first and second electrodes 48, 50 and to first and second electrical buses 52, 54, respectively. As shown in FIG. 3, the electrocaloric films are disposed in the stack with a configuration such that the relative (top/bottom) orientation of the first and second electrodes 48, 50 is alternated with adjacent films so that each fluid flow path 44 has electrodes of matching polarity on each side of the fluid flow path 44, which can inhibit arcing across the flow path gap.

It should be noted that although the FIGS. 2A, 2B, and 3 disclose individual segments of electrocaloric film attached to a peripheral frame in a picture-frame configuration, other configurations of electrocaloric articles can be utilized such as electrocaloric articles formed from a continuous sheet of electrocaloric film, or different frame configurations such as internal frame components (e.g., stack spacers) or peripheral frames covering less than the full perimeter of the electrocaloric film, or combinations of the above features with each other or other features. An example embodiment of a configuration with the above-referenced features is schematically shown in FIG. 4, in which an electrocaloric film 62 comprises an electrocaloric polymer film 64 with a first electrode 66 on a first side of the film and a second electrode 68 on a second side of the film. As shown in FIG. 4, a continuous sheet of the electrocaloric film 62 is shown folded back and forth to provide a plurality of connected aligned segments 70 arranged in a stack-like configuration with gaps 72 between the electrocaloric film segments 70. The gaps 72 can provide a flow path in a direction into or out of the page for a working fluid such as air or a heat transfer fluid. The gaps 72 between the electrocaloric film are maintained by internal frame components in the form of spacers 74 disposed in the gaps 72 between the aligned electrocaloric film segments 70. An electrical bus end cap 76 provides an electrical connection to the electrode 68, and an electrical bus end cap 78 provides an electrical connection to the electrode 66. In some embodiments, the electrodes can be connected to a power control circuit (not shown). In some embodiments, the electrode 68 and electrical bus end cap 76 can be connected to a voltage ground, and the electrode 66 and the electrical bus end cap 78 can be connected to a non-ground voltage. As further shown in FIG. 4, the end caps 76/78 can serve as an external frame component attached along peripheral portion of the electrocaloric film 62 extending along edges parallel with a direction of fluid flow, allowing fluid inlet and outlet peripheral portions to be free of any external frame components, and spacers 74 can serve as internal frame components.

Variations can of course be made on this design. For example, FIG. 4 shows the electrodes 66 and 68 extending continuously along the continuous sheet of electrocaloric film 62, which allows for a direct electrical connection to the end caps 26/28, which can serve as an electrical bus if they are electrically conductive. However, the metalized layers for the electrodes 66/68 can also be discontinuous, with electrical connections being provided through the spacers 74 or by one or more separate electrical leads extending through an external frame (not shown). Discontinuous metalized layers can be used, for example, in combination with separate electrical connections to a power circuit (not shown) to allow for individual control or activation of any one or combination of the segments 70 of the electrocaloric film. The continuous sheet of electrocaloric film 62 can be dispensed directly from a roll and manipulated by bending back and forth into a stack-like configuration, or can be cut into a pre-cut length and bent back and forth into the stack-like configuration. Additional disclosure regarding continuous sheet electrocaloric articles can be found in PCT published application no. WO2017/111916 A1, and in U.S. patent application Ser. No. 62/722,736, the disclosures of both of which are incorporated herein by reference in their entirety.

It has been discovered that electrocaloric films can be subject to stress and strain during operation, as the electrocaloric material is subjected to realignment of atoms or molecules in the electrocaloric material in response to application and removal of an electric field. It has been further discovered that stress electrocaloric films can be subject to concentration of stress at locations in the electrocaloric film. The occurrence of stress in electrocaloric films can lead to a loss of efficiency, or to failure to meet system design parameters, and even to failure of entire segments of electrocaloric film. As further described below, different stress management mechanisms can be utilized in electrocaloric articles.

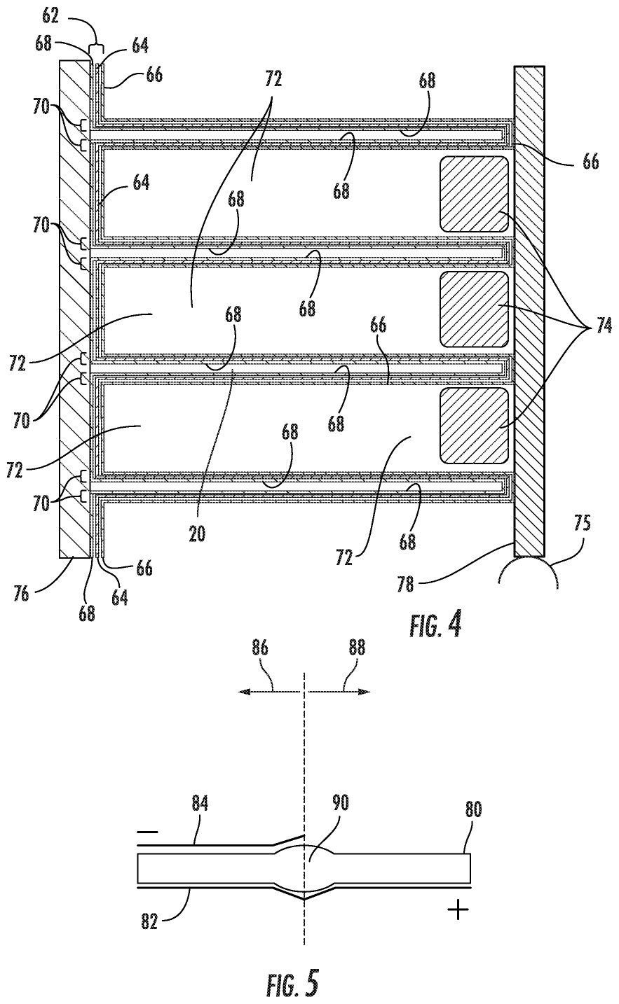

With reference now to FIG. 5, an example embodiment is shown in which an electrocaloric film is thicker at an edge of an active area. As shown in the cross-sectional view of FIG. 5, an electrocaloric film 80 includes a first electrode 82 that is energized to a first voltage during activation of the electrocaloric material and a second electrode 84 that is maintained at a ground state or energized to a different voltage than the first electrode 82 during activation. The portion of the electrocaloric film 80 that is between the electrodes 82 and 84 is thus activated during energization of the electrodes and the portion of the electrocaloric film not between the electrodes 82 and 84 is not activated during energization of the electrodes. The unnumbered dashed line shown in FIG. 5 thus represents an edge between an active area on side 86 of the dashed line and a non-active area on side 88 of the dashed line. It has been discovered that in some embodiments stress can be concentrated at an edge of an active area of an electrocaloric film, and that such stress concentration can be managed by an increase in thickness of the electrocaloric film at an edge of an active area of the film. Accordingly, as shown in FIG. 5, the electrocaloric film 80 is provided with an increased thickness 90 at the edge of the active area. The degree of thickness increase can depend on a number of factors such as the physical characteristics of the film, placement of electrodes, voltages applied to the electrodes, and numerous other factors. In some embodiments, the thickness of the film can be increased by 20%, or 50%, or 100%, or 200%, compared to the film thickness in the active area, or compared to the film thickness in the non-active area, or compared to the film thickness in thinner of the active area and the non-active area.

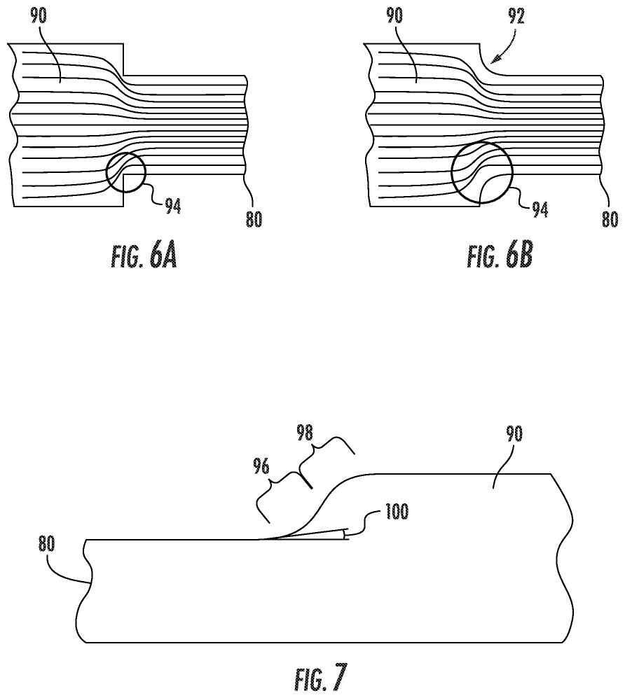

In some embodiments stress at a location where the thickness of the electrocaloric film changes can be managed by providing a region of the film with a continuous change in thickness between a first location at a first thickness and a second thickness. In some embodiments, the first and/or second locations can be locations at which thickness of the film is or becomes constant. Provision of a continuous change in thickness, compared to a step change or instantaneous change in thickness (e.g., a vertical wall on the film surface) can help manage stress. The example embodiment shown in FIG. 5 includes a region with a continuous change in thickness, and another example embodiment of a continuous change in thickness provided by a fillet configuration is shown in FIGS. 6A and 6B, which carry over numbering from FIG. 5. FIG. 6A shows a step change or instantaneous change between a thinner region of the electrocaloric film 80 and a thicker region 90. FIG. 6B shows the change in thickness with a fillet 92 between the vertical and horizontal surfaces to provide a region of continuous thickness change. Un-numbered stress lines are shown within the electrocaloric film 80 and a comparison of these stress lines between FIGS. 6A and 6B in region 94 shows a reduction in stress concentration provided by the fillet 92. The fillet 92 is shown between two adjacent surfaces having a 90° angle between them, but can be used between any adjacent surfaces with an angle between them greater than 0° and less than 180°. The fillet can be made of the same material as the film or can be a supplemental material connected to the film material to allow transmission of stress between the materials.

Another example embodiment of a continuous change in thickness is shown in FIG. 7, which carries forward some of the same numbering from FIGS. 5 and 6A-6B to describe like elements. FIG. 7 shows a continuous change between a thinner region of the electrocaloric film 80 and a thicker region 90, with a surface profile in the region of thickness change that is concave in region 96 that transitions from a thinner region of and that is convex in region 98 that transitions from the thicker region 90. In some embodiments, this surface profile with a combination of concave and convex regions can be characterized by a sigmoid function. In some embodiments, a change in thickness of an electrocaloric film can include a surface departure angle from a surface portion of constant thickness, shown in FIG. 7 as angle 100. In some embodiments, a surface departure angle of less than or equal to 5°, or less than or equal to 15°, or less than or equal to 30°, or less than or equal to 45°. The surface departure angle a departure angle can be from a thinner film portion transitioning to a thicker film portion (as shown in FIG. 7), or can be from a thicker film portion transitioning to a thinner film portion.

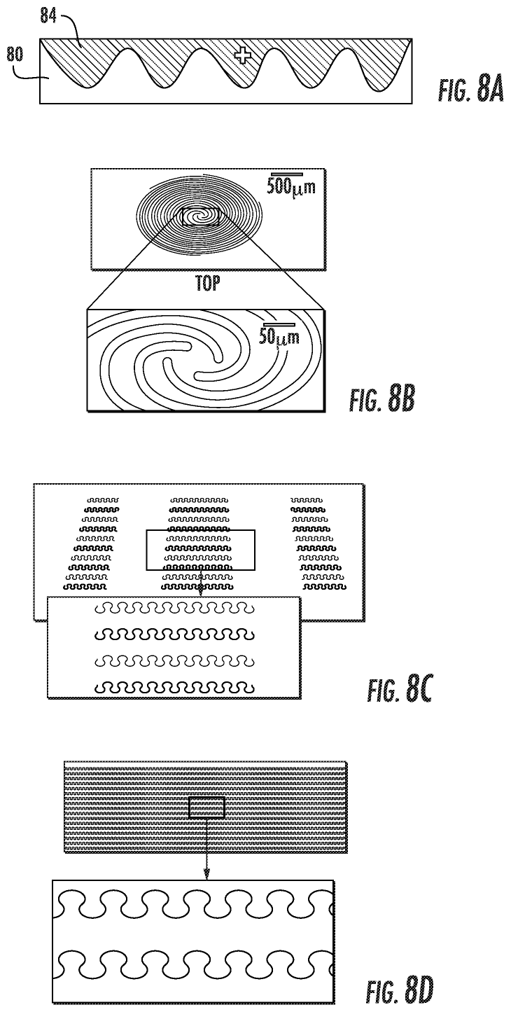

In some embodiments, an electrode on the electrocaloric film can include a configuration designed including a non-linear edge to promote management of stress in the electrocaloric film. Example embodiments of such electrode configurations are shown in FIGS. 8A-8D. Each of FIGS. 8A, 8B, 8C, and 8D shows an electrode with a non-linear edge, with FIG. 8A using numbering from FIG. 5, and FIGS. 8B, 8C, and 8D each showing a lower-magnification upper image and a higher-magnification lower image of example embodiments of curved or complex-shaped linear extensions. In some embodiments a non-linear (i.e., not in a single straight line), with curved, non-aligned straight, or complex edge configurations, including multi-segment or complex shaped linear extensions, can provide a technical effect of promoting the accommodation of stress or strain in multiple directions, and in some embodiments can promote the accommodation of stress or strain from any direction (i.e., omnidirectional). Other electrode pattern configurations can be used besides spacer area-separated linear extensions. For example, a thickness variation of the electrode conductive material in a direction normal to the film surface (which can be repeated across the surface) can provide a configuration with a wave-like structure or pattern that can absorb stress or strain in a direction along (parallel to) the film surface. Also, alternative embodiments could include electrodes configured with a pattern of an otherwise contiguous metallization field with spacer areas of circular, ovular, polygonal, or other shapes randomly or regularly placed in the metallization field. Various shaped electrodes can be applied using patterned electrode application techniques such as masking, ink jetting, film transfer, and other techniques such as those described in PCT application number PCT/US2018/038052, the disclosure of which is incorporated herein by reference in its entirety.

In some embodiments an electrocaloric film segment can include a non-active film area interposed between an active film area and a frame or frame component in order to promote stress management. An example embodiment of such an electrocaloric film segment is shown in FIG. 9, which uses some of the same numbering from FIG. 3 to describe like elements. FIG. 9 schematically shows a cross-sectional view of a framed electrocaloric film segment from a stack of segments such as shown in FIG. 3. As shown in FIG. 9, an electrocaloric film 46 is disposed in a frame 10 with electrodes 48 and 50 on each side of the electrocaloric film 46, and adjacent spacers 42. The electrocaloric film 46 includes an active area 45 in which the film is activated by energization of the electrodes 48/50. The electrocaloric film 46 also includes non-active areas 47 and 49 disposed between the active area 45 and the frame 10. As disclosed herein the non-active area 47 and or the non-active area 49 can provide a separation of at least 10 times, or 100 times, or 200 times the thickness of the electrocaloric film between the active area and the frame where larger separation can be needed for softer, lower modulus films (e.g. unfilled thin polymer electrocaloric films, and less separation would be needed for higher modulus films (e.g. ceramic films).

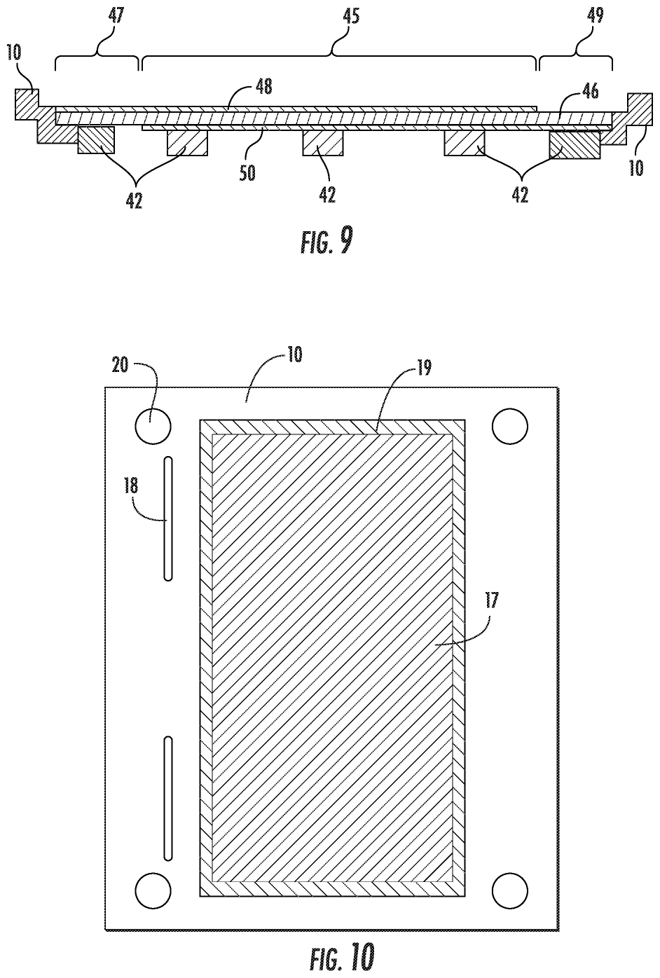

In some embodiments an electrocaloric film segment can include an elastic interface interposed between an active film area and a frame or frame component in order to promote stress management. An example embodiment of a top view of such an electrocaloric film segment is shown in FIG. 10, which uses some of the same numbering from FIG. 1 to describe like elements. As shown in FIG. 10, an electrocaloric film 17 is disposed in a frame 10, and an elastic interface 19 is disposed between the electrocaloric film segment 17 and the frame 10. In some embodiments, the elastic interface 19 can be an elastomeric film or sheet disposed between the film segment 17 and the frame 10, and attached for example by adhesive. In some embodiments, an elastomer for the elastic interface 10 can have a modulus of elasticity higher than a modulus of elasticity of an electrocaloric polymer film segment 17. In some embodiments, an elastomer for the elastic interface can have a modulus of elasticity of less than or equal to: 1000 Megapascals, 500 Megapascals, or 200 Megapascals. Various types of elastomers can be used for the elastic interface 19, including but not limited to polysiloxanes, polyisoprenes, polybutadienes, EPM or EPDM elastomers, thermoplastic elastomers (e.g., polyurethane), styrene-butadiene copolymer elastomers, and numerous other rubber or other elastomeric polymers. Non-polymeric elastic interfaces can be used as well, for example, a metal spring integrated into the frame 10 to provide an elastic response at the film/frame interface.

In some embodiments an electrocaloric film segment can include a movable or deformable frame component in order to promote stress management. Such an embodiment is schematically shown in FIG. 4, where a flexible mounting base 75 allows for limited movement of the end cap 78. The flexible mounting base 75 is shown in a simplified schematic form, but can be any type of flexible mounting base, including but not limited to mounting bases that allow for limited movement on along various axes of displacement such as 1-axis, 2-axis, 3-axis, or 5-axis displacements. The mounting base 75 can utilize both metallic and elastomeric elastic materials to provide for limited movement, as well as displaceable joints (e.g., ball/socket joints) and other movable configurations. Movable frame components are not limited to an entire frame, and displaceability can be provided to only portions of a frame.

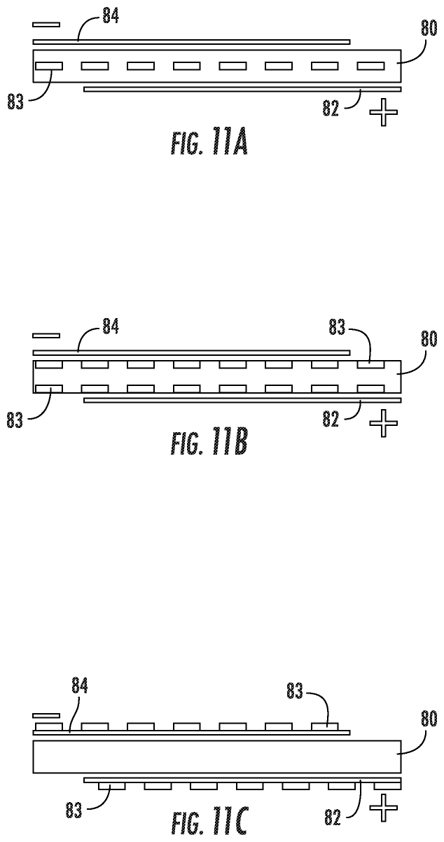

In some embodiments, a reinforcing material disposed in or on an electrocaloric film segment or an electrode can promote film stress management. Example embodiments of reinforcing materials are shown in FIGS. 11A, 11B, and 11C. The reinforcing material can be any type of reinforcing material or mechanical strengthening material such as used for composite materials, including mesh or sheet reinforcements as well as fiber fillers in the form of whiskers, needles, rods, tubes, strands, elongated platelets, lamellar platelets, ellipsoids, micro fibers, nanofibers and nanotubes, elongated fullerenes, and the like. A mesh or sheet can be woven from extended length fibers or can be extruded (e.g., as a thermoplastic). Materials for reinforcing material include glass or mineral fibers (e.g., aluminum silicates), ceramic fibers (e.g., silicon carbide), polymers in fiber form, mesh form, or solid sheet form, including but not limited to polyethylene terephthalate, polybutylene terephthalate and other polyesters, polyarylates, polyethylene, polyvinylalcohol, polytetrafluoroethylene, acrylic resins, aromatic polyamides, polyaramid fibers, polybenzimidazole, polyimide fibers such as polyimide 2080 and PBZ fiber; and polyphenylene sulfide, polyether ether ketone, polyimide, polybenzoxazole, aromatic polyimides or polyetherimides, and the like. Combinations of any of the foregoing materials can also be used.

The reinforcing material can be disposed in different locations as shown in FIGS. 11A, 11B, and 11C, which uses some of the same numbering as FIG. 5 to describe like elements. In some embodiments, a reinforcing material 83 can be disposed within an electrocaloric film 80 as shown in FIG. 11A, either as chopped fibers or as a mesh or as a solid sheet. In some embodiments, a reinforcing material 83 can be disposed on an electrocaloric film 80 as shown in FIG. 11B. In some embodiments, the reinforcing material 83 on the electrocaloric film as shown in FIG. 11B can be a mesh or solid sheet that is either attached (e.g., by adhesive or by attaching the reinforcing material during film fabrication before the film has solidified after coating) to the electrocaloric film or it simply lies on the film. As further shown in FIG. 11B the electrodes 82 and 84 can be disposed over the reinforcing material 83. In some embodiments, a reinforcing material 83 can be disposed on electrode 82 and/or electrode 84 as shown in FIG. 11C. In some embodiments, the reinforcing material 83 on the electrode(s) as shown in FIG. 11C can be a mesh or solid sheet that is either attached (e.g., by adhesive or by attaching the reinforcing material during film fabrication before the film has solidified after coating) to the electrode or it simply lies on the electrode.

Although any directions described herein (e.g., “up”, “down”, “top”, “bottom”, “left”, “right”, “over”, “under”, etc.) are considered to be arbitrary and to not have any absolute meaning but only a meaning relative to other directions. For convenience, unless otherwise indicated, the terms shall be relative to the view of the Figure shown on the page, i.e., “up” or “top” refers to the top of the page, “bottom” or “under” refers to the bottom of the page, “right” to the right-hand side of the page, and “left” to the left-hand side of the page.

The term “about” is intended to include the degree of error associated with measurement of the particular quantity based upon the equipment available at the time of filing the application. For example, “about” can include a range of±8% or 5%, or 2% of a given value.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A heat transfer system, comprising
a plurality of supported electrocaloric film segments arranged in a stack and connected to a frame;
a working fluid flow path through the stack between adjacent electrocaloric film segments, said working fluid flow path in operative thermal communication with a heat sink and a heat source at opposite ends of the working fluid flow path;
a plurality of electrodes arranged to generate an electric field in the electrocaloric film segments, and connected to a power source configured to selectively apply voltage to activate the electrodes in coordination with fluid flow along the working fluid flow path to transfer heat from the heat source to the heat sink, said heat transfer system further comprising a film stress management mechanism selected from:
a change in electrocaloric film thickness from a first film thickness at a first location on an electrocaloric film segment to a second film thickness at a second location on the electrocaloric film segment, wherein the change in electrocaloric film thickness includes a continuous change in thickness from the first thickness to the second thickness, or wherein the first location is at an edge of an active area of the electrocaloric film and the second location is remote from said edge of the active area of the electrocaloric film; or
an electrode comprising an electrically-conductive material on a surface portion of an electrocaloric film segment surface that includes a non-linear edge between the electrically-conductive surface portion and the electrocaloric film segment surface outside of the electrically conductive surface portion; or
an electrocaloric film segment that includes an active area and a non-active area, and the non-active area is interposed between the frame and the active area to provide a separation between the active area and the frame of at least 10 times the thickness of the electrocaloric film; or
an elastic interface between an electrocaloric film segment and the frame; or
a movable or deformable frame component; or
a reinforcing material disposed in or on an electrocaloric film segment or an electroctrode.

2. The heat transfer system of claim 1, wherein the stress management mechanism includes a change in electrocaloric film thickness from a first film thickness at a first location on an electrocaloric film segment to a second film thickness at a second location on the electrocaloric film segment, wherein the change in electrocaloric film thickness includes a continuous change in thickness from the first thickness to the second thickness, or wherein the first location is at an edge of an active area of the electrocaloric film and the second location is remote from said edge of the active area of the electrocaloric film.

3. The heat transfer system of claim 2, wherein the change in electrocaloric film thickness includes a continuous change in thickness from the first thickness to the second thickness.

4. The heat transfer system of claim 2, wherein the first location is at an edge of an active area of the electrocaloric film and the second location is remote from said edge of the active area of the electrocaloric film.

5. The heat transfer system of claim 4, wherein the electrocaloric film has said second thickness at locations on both sides of said edge of the active area.

6. The heat transfer system of claim 2, wherein the change in electrocaloric film thickness includes surface departure angle of less than 45° from a surface portion of constant thickness.

7-9. (canceled)

10. The heat transfer system of any of claim 2, wherein electrocaloric film surface includes a fillet configuration on an angle between adjacent surfaces.

11. The heat transfer system of any of claim 2, wherein the change in electrocaloric film thickness includes a film surface profile that includes a convex portion and a concave portion.

12. The heat transfer system of claim 1, wherein the stress management mechanism includes an electrode comprising an electrically-conductive material on a surface portion of an electrocaloric film segment surface that includes a non-linear edge between the electrically-conductive surface portion and the electrocaloric film segment surface outside of the electrically conductive surface portion.

13. The heat transfer system of claim 12, wherein the electrode comprises a patterned disposition of conductive material comprises a plurality of areas on the film surface comprising the conductive material separated by spacer areas on the film that do not comprise the conductive material.

14. The heat transfer system of claim 12, wherein the electrode is configured as a plurality of electrically connected linear extensions of conductive material along the film surface separated by spacer areas.

15. The heat transfer system of claim 1, wherein the stress management mechanism includes an electrocaloric film segment that includes an active area and a non-active area, and the non-active area is interposed between the frame and the active area to provide a separation between the active area and the frame of at least 10 times the thickness of the electrocaloric film.

16. (canceled)

17. The heat transfer system of claim 15, wherein the stress management mechanism includes an electrocaloric film segment that includes an active area and a non-active area, and the non-active area is interposed between the frame and the active area to provide a separation between the active area and the frame of at least 200 times the thickness of the electrocaloric film.

18. The heat transfer system of claim 1, wherein the stress management mechanism includes a movable or deformable frame component.

19. The heat transfer system of claim 1, film segment and the frame.

20. The heat transfer system of claim 1 electrocaloric film segment or an electroctrode.

21. The heat transfer system of claim 20, wherein the reinforcing material is disposed in or on an electrocaloric film segment.

22. (canceled)

23. The heat transfer system of any of claim 20, wherein the reinforcing material is disposed on an electrode.

24. The heat transfer system of any of claim 20, wherein the reinforcing material includes a mesh.

25. The heat transfer system of claim 20, wherein the reinforcing material includes a solid sheet.
